(19) United States
(12) Patent Application Publication
(10) Pub. No.: US 2011/0272444 A1
(43) Pub. Date: Nov. 10, 2011

(54) SUPPORTING DEVICE OF INTELLIGENT TERMINAL EQUIPMENT AND SUPERMARKET SHOPPING CART

(75) Inventor: Jianqiang Zhang, Beijing (CN)

(73) Assignee: China Human International Technology Co. LTD., Chaoyang District, Beijing (CN)

(21) Appl. No.: 13/143,847

(22) PCT Filed: Sep. 23, 2009
(86) PCT No.: PCT/CN2009/074135

§ 371 Date: Jul. 8, 2011

(30) Foreign Application Priority Data
Jan. 22, 2009 (CN) 200920005102.7

(51) Int. Cl. B60R 7/00; H05K 7/00

(52) U.S. Cl. 224/411; 248/309.1

(57) ABSTRACT

A supporting device of an intelligent terminal equipment and a supermarket shopping cart provided with the supporting device are disclosed. The supporting device of an intelligent terminal equipment includes a mounting member (101), a first supporting member (102) and a second supporting member (103). The rear end of the first supporting member (102) is fixed with the front side of the mounting member (101), and the rear end of the second supporting member (103) is fixed with the front side of the mounting member (101). The front end of the first supporting member (102) and the front end of the second supporting member (103) are connected by a first supporting joint member (104). The first supporting member (102), the second supporting member (103) and the first supporting joint member (104) are used to support the intelligent terminal equipment. The supporting device of an intelligent terminal equipment is mounted on the handle of a supermarket shopping cart by plastic bayonets and screws. After assembling plastic bayonets and screws are mounted, the intelligent terminal equipment is fixed on the first supporting member, the second supporting member and the first supporting joint member. This structure does not require rebuilding the cart body, and the cost of reforming is low.

The present application claims the benefit of priority to Chinese patent application No. 200920005102.7 titled “SUPPORTING DEVICE OF INTELLIGENT TERMINAL EQUIPMENT AND SUPERMARKET SHOPPING CART”, filed with the Chinese State Intellectual Property Office on Jan. 22, 2009. The entire disclosure thereof is incorporated herein by reference.

### TECHNICAL FIELD OF THE INVENTION

The present invention relates to a technical field of shopping carts, particularly to a supporting device of an intelligent terminal equipment and a supermarket shopping cart.

### BACKGROUND OF THE INVENTION

In many large supermarkets, a shopping cart is provided with an intelligent terminal equipment which can provide various services for the customers to facilitate the shopping of the customers. When the customers do shopping with the shopping cart, the intelligent terminal equipment on the shopping cart can help customers inquire the position of the commodity, provide an intelligent navigation, inquire the price of the commodity, inquire the quality information of the commodity and the information relating to the commodity and the like; and also can complete payment via an electronic wallet; and can also play video advertisements of current commodities on the counters automatically and provide statistics of the played number of the video advertisements.

Due to the weight of the intelligent terminal equipment, when installing the intelligent terminal equipment onto the shopping cart, it is necessary to provide a device for supporting and fixing the intelligent terminal equipment on the cart body of the supermarket shopping cart. In the prior method, generally, it is necessary to rebuild a new cart body, on which a structure for supporting and fixing the intelligent terminal equipment is provided. Thus, in this method, the manufacturing cost is increased due to the rebuilt cart body.

### SUMMARY OF THE INVENTION

In view of the above disadvantage in the prior art, that is, when the intelligent terminal equipment is installed on the supermarket shopping cart, the manufacturing cost is increased since it is necessary to rebuild a new cart body, the present invention provides a supporting device for an intelligent terminal equipment.

A supporting device of an intelligent terminal equipment includes a mounting member, a first supporting member and a second supporting member. A back end of the first supporting member is fixedly connected with a front side of the mounting member, and a back end of the second supporting member is fixedly connected with the front side of the mounting member. A first supporting joint member is connected between a front end of the first supporting member and a front end of the second supporting member. The first supporting member, the second supporting member and the first supporting joint member are used to support the intelligent terminal equipment.

Preferably, the first supporting joint member is a steel sheet.

Preferably, the first supporting member and the second supporting member are both square steel tubes.

Preferably, the mounting member is a standard handle for the supermarket shopping cart.

Preferably, a second supporting joint member is connected between the back end of the first supporting member and the back end of the second supporting member.

Preferably, the second supporting joint member is a steel sheet.

Preferably, the first supporting member, the second supporting member and the mounting member are connected by welding.

Preferably, the first supporting member and the second supporting member are both of a bending structure. A distance between the back end of the first supporting member and the back end of the second supporting member is smaller than a distance between the front end of the first supporting member and the front end of the second supporting member.

A supermarket shopping cart includes the above supporting device of the intelligent terminal equipment, and the mounting member is installed at a handle of the supermarket shopping cart.

Preferably, the second supporting joint member is connected to a steel bar at the upper edge of the back portion of the cart body with screws and connecting bayonets.

The supporting device of the intelligent terminal equipment according to the present invention includes a mounting member, a first supporting member, a second supporting member and a first supporting joint member. The first supporting member and the second supporting member are fixedly connected to the mounting member. The first supporting member, the second supporting member and the first supporting joint member are used to support the intelligent terminal equipment. Among constituting parts of the cart body of the supermarket shopping cart, most of them are connected by welding, except that the handle is connected to the cart body by screws and plastic bayonets. Thus, the handle can be disassembled from the cart body by loosing the screws and the plastic bayonets. In view of this, the present invention performs a modification to the handle, that is, the first supporting member, the second supporting member and the first supporting joint member, which perform the supporting function, are fixedly connected onto the standard handle, so as to constitute the supporting device of the intelligent terminal equipment. The supporting device of the intelligent terminal equipment is mounted at the handle of the supermarket shopping cart and the plastic bayonets and screws are then fastened, in this way, the modification to the supermarket shopping cart is accomplished. It is unnecessary for this configuration to rebuild a new cart body, thereby having a low manufacturing cost.

The intelligent terminal equipment may be fixed onto the first supporting member, the second supporting member and the first supporting joint member. A display screen of the intelligent terminal equipment is perpendicular to the sight line of the consumer. Thus when pushing the supermarket shopping cart, the customer can see the display screen comfortably by naturally lowering his head. Since a keyboard of the intelligent terminal equipment is disposed close to the handle, when pushing the supermarket shopping cart, the customer can press the keyboard by moving his hand in a minimum distance without affecting the holding of the handle.

In a preferred technical solution, the second supporting joint member for fixing the first supporting member and the second supporting member is welded between the back end of the first supporting member and the back end of the second supporting member. The second supporting joint member is connected to a steel bar of the upper edge of the back portion of the cart body of the supermarket shopping cart with screws and connecting bayonets. The steel bar of the upper edge of the back portion of the cart body has elasticity, and with this elasticity, the supporting device of the intelligent terminal equipment has an anti-vibration capacity which can protect the intelligent terminal equipment effectively. Besides, since the second supporting joint member is fixed on the upper edge of the back portion of the cart body, the second supporting joint member may support the first supporting member and the second supporting member in a vertical direction.

The present invention further provides a supermarket shopping cart installed with the above-mentioned supporting device of the intelligent terminal equipment. Since the above-mentioned supporting device of the intelligent terminal equipment has the above-mentioned technical effects, the supermarket shopping cart installed with the supporting device of the intelligent terminal equipment also has the above-mentioned technical effects.

### BRIEF DESCRIPTION OF DRAWINGS

FIG. 1 is a schematic view of the structure of a supporting device of an intelligent terminal equipment according to a first embodiment of the present invention; and

FIG. 2 is a schematic view of the structure of a supporting device for an intelligent terminal equipment according to a second embodiment of the present invention;

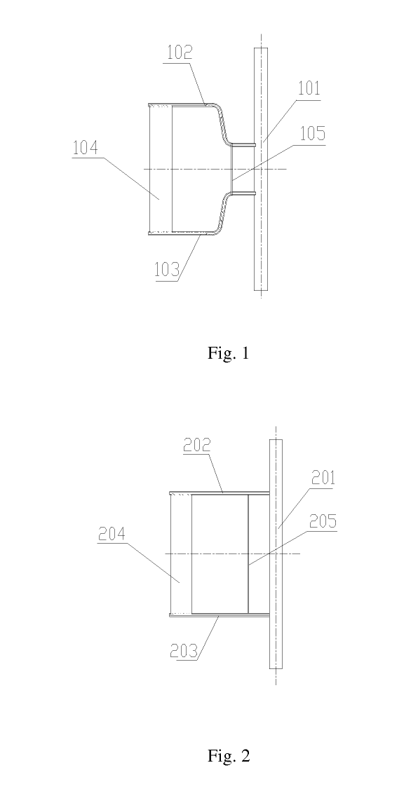

Reference numerals in FIGS. 1 and 2:

| | |
|---|---|
| 101. mounting member, | 102. first supporting member, |
| 103. second supporting member, | 104. first supporting joint member, |
| 105. second supporting joint member; | |
| 201. mounting member, | 202. first supporting member, |
| 203. second supporting member, | 204. first supporting joint member, |
| 205. second supporting joint member. | |

### DETAILED DESCRIPTION OF THE INVENTION

The present invention will be described hereinafter in conjunction with drawings. The following description is only demonstrative and explanatory, and should not be deemed to limit the protection scope of the present invention.

Referring to FIG. 1, a schematic view of the structure of a supporting device of an intelligent terminal equipment according to a first embodiment of the present invention is shown.

As shown in FIG. 1, the supporting device of the intelligent terminal equipment includes a mounting member 101, a first supporting member 102, a second supporting member 103, a first supporting joint member 104 and a second supporting joint member 105. The mounting member 101 is a standard handle cooperated with a cart body of a supermarket shopping cart. The first supporting member 102 and the second supporting member 103 are bent square steel tubes. The first supporting joint member 104 and the second supporting joint member 105 are steel sheets.

The back end of the first supporting member 102 is fixed with the front side of the mounting member 101 by welding, and the back end of the second supporting member 103 is fixed with the front side of the mounting member 101 by welding. The first supporting member 102 and the second supporting member 103 are both of a bending structure. The distance between the back end of the first supporting member 102 and the back end of the second supporting member 103 is smaller than the distance between the front end of the first supporting member 102 and the front end of the second supporting member 103. The first supporting joint member 104 for supporting the intelligent terminal equipment is welded between the front end of the first supporting member 102 and the front end of the second supporting member 103, and the second supporting joint member 105 is welded between the back end of the first supporting member 102 and the back end of the second supporting member 103.

The advantages of the supporting device of the intelligent terminal equipment are presented as follows.

Among constituting parts of the cart body of the supermarket shopping cart, most of them are connected by welding, except that the handle is connected to the cart body by screws and plastic bayonets. Thus, the handle can be disassembled from the cart body by loosing the screws and the plastic bayonets. In view of this, the present invention performs a modification to the handle, that is, the first supporting member 102, the second supporting member 103, the first supporting joint member 104 and the second supporting joint member 105 which perform the supporting function are fixedly connected onto the standard handle, so as to constitute the supporting device of the intelligent terminal equipment. The supporting device of the intelligent terminal equipment is mounted at the handle of the supermarket shopping cart and the plastic bayonets and screws are then fastened, in this way, the modification to the supermarket shopping cart is accomplished. It is unnecessary for this configuration to rebuild a new cart body, thereby having a low manufacturing cost.

The intelligent terminal equipment may be fixed onto the first supporting member 102, the second supporting member 103 and the first supporting joint member 104. A display screen of the intelligent terminal equipment is disposed perpendicular to the sight line of the consumer. Thus, when pushing the supermarket shopping cart, the customer can see the display screen comfortably by naturally lowering his head. Since a keyboard of the intelligent terminal equipment is disposed close to the handle, when pushing the supermarket shopping cart, the customer can press the keyboard by moving his hand in a minimum distance without affecting the holding of the handle.

In a preferred technical solution, the second supporting joint member 105 for fixing the first supporting member 102 and the second supporting member 103 is welded between the back end of the first supporting member 102 and the back end of the second supporting member 103. The second supporting joint member 105 is connected to a steel bar of the upper edge of the back portion of the cart body of the supermarket shopping cart with screws and connecting bayonets. The steel bar of the upper edge of the back portion of the cart body has elasticity, and with this elasticity, the supporting device of the intelligent terminal equipment has an anti-vibration capacity which can protect the intelligent terminal equipment effectively. Besides, since the second supporting joint member 105 is fixed on the upper edge of the back portion of the cart body, the second supporting joint member 105 may support the first supporting member 102 and the second supporting member 103 in a vertical direction.

In the above embodiment, the first supporting member and the second supporting member are both bent square steel tubes. Alternatively, the first supporting member and the second supporting member may be straight square steel tubes. Both of the above structures fall within the protection scope of the present invention. The latter structure will be briefly described in the second embodiment of the present invention.

Referring to FIG. 2, a schematic view of the structure of a supporting device of an intelligent terminal equipment according to the second embodiment of the present invention is shown.

As shown in FIG. 2, the supporting device of the intelligent terminal equipment includes a mounting member 201, a first supporting member 202, a second supporting member 203, a first supporting joint member 204 and a second supporting joint member 205. The mounting member 201 is a standard handle cooperated with a cart body of a supermarket shopping cart. The first supporting member 202 and the second supporting member 203 are straight square steel tubes. The first supporting joint member 204 and the second supporting joint member 205 are steel sheets.

The back end of the first supporting member 202 is fixed with the front side of the mounting member 201 by welding, and the back end of the second supporting member 203 is fixed with the front side of mounting member 201 by welding. The first supporting member 202 and the second supporting member 203 are both straight square steel tubes and are disposed in parallel. The first supporting joint member 204 for supporting the intelligent terminal equipment is welded between the front end of the first supporting member 202 and the front end of the second supporting member 203, and the second supporting joint member 205 is welded between the back end of the first supporting member 202 and the back end of the second supporting member 203.

The other details are similar to that in the first embodiment, and thus will not be described in detail herein.

In the above embodiments, the material of the first supporting member and the second supporting member is square steel tube, but any metal material with relatively high strength can be used to make the first supporting member and the second supporting member. These structures fall within the protection scope of the present invention.

In the above embodiments, the supporting device of the intelligent terminal equipment is formed by separate members such as the first supporting member, the second supporting member, the first supporting joint member and the second supporting joint member etc. Alternatively, the supporting device of the intelligent terminal equipment according to the invention may also be formed as an integral structure by casting with a mold. The two structures fall within the protection scope of the present invention.

The present invention further provides a supermarket shopping cart installed with the above-mentioned supporting device of the intelligent terminal equipment. Since the above-mentioned supporting device of the intelligent terminal equipment has the above-mentioned technical effects, the supermarket shopping cart installed with the supporting device of the intelligent terminal equipment also has the above-mentioned technical effects, which will not be described in detail herein.

The above description is only the preferred embodiments of the present invention. It should be noted that, due to the limitation of the written expression and limitless concrete structures, for the person skilled in the art, many improvements and modifications may be made without departing from the principle of the present invention and these improvements and modifications should be deemed to fall into the protection scope of the present invention.

1. A supporting device of an intelligent terminal equipment, comprising a mounting member, a first supporting member and a second supporting member, wherein a back end of the first supporting member is fixedly connected with a front side of the mounting member, a back end of the second supporting member is fixedly connected with the front side of the mounting member, a first supporting joint member is connected between a front end of the first supporting member and a front end of the second supporting member, and the first supporting member, the second supporting member and the first supporting joint member are configured to support the intelligent terminal equipment.

2. The supporting device of the intelligent terminal equipment according to claim 1, wherein the first supporting joint member is a steel sheet.

3. The supporting device of the intelligent terminal equipment according to claim 1, wherein the first supporting member and the second supporting member are both square steel tubes.

4. The supporting device of the intelligent terminal equipment according to claim 1, wherein the mounting member is a standard handle for a supermarket shopping cart.

5. The supporting device of the intelligent terminal equipment according to claim 1, wherein a second supporting joint member is connected between the back end of the first supporting member and the back end of the second supporting member.

6. The supporting device of the intelligent terminal equipment according to claim 5, wherein the second supporting joint member is a steel sheet.

7. The supporting device of the intelligent terminal equipment according to claim 1, wherein the first supporting member, the second supporting member and the mounting member are connected by welding.

8. The supporting device of the intelligent terminal equipment according to claim 1, wherein the first supporting member and the second supporting member are both of a bending structure, and a distance between the back end of the first supporting member and the back end of the second supporting member is smaller than a distance between the front end of the first supporting member and the front end of the second supporting member.

9. A supermarket shopping cart, comprising the supporting device of the intelligent terminal equipment as claimed claim 1, wherein the mounting member is installed at a handle of the supermarket shopping cart.

10. The supermarket shopping cart according to claim 9, wherein the second supporting joint member is connected to a steel bar of an upper edge of a back portion of the cart body with screws and connecting bayonets.

11. The supermarket shopping cart according to claim 9, wherein the first supporting joint member is a steel sheet.

12. The supermarket shopping cart according to claim 9, wherein the first supporting member and the second supporting member are both square steel tubes.

13. The supermarket shopping cart according to claim 9, wherein the mounting member is a standard handle for the supermarket shopping cart.

14. The supermarket shopping cart according to claim 9, wherein a second supporting joint member is connected between the back end of the first supporting member and the back end of the second supporting member.

15. The supermarket shopping cart according to claim 9, wherein the second supporting joint member is a steel sheet.

16. The supermarket shopping cart according to claim 9, wherein the first supporting member, the second supporting member and the mounting member are connected by welding.

17. The supermarket shopping cart according to claim 9, wherein the first supporting member and the second supporting member are both of a bending structure, and a distance between the back end of the first supporting member and the back end of the second supporting member is smaller than a distance between the front end of the first supporting member and the front end of the second supporting member.
